(19) United States
(12) Patent Application Publication
(10) Pub. No.: US 2017/0181316 A1
(43) Pub. Date: Jun. 22, 2017

(54) HEAT DISSIPATING DEVICE AND SWING STRUCTURE THEREOF

(71) Applicant: HSIEN-CHIN SU, TAINAN CITY (TW)

(72) Inventor: HSIEN-CHIN SU, TAINAN CITY (TW)

(21) Appl. No.: 15/362,445

(22) Filed: Nov. 28, 2016

(30) Foreign Application Priority Data
Dec. 18, 2015 (TW) 104220363

(51) Int. Cl. H05K 7/20; G06F 1/20

(52) U.S. Cl. CPC H05K 7/20172; G06F 1/20

(57) ABSTRACT

A swing structure of a heat dissipating device includes an elongated blade and a magnetic actuation disposed on the blade. The blade has a loading segment and a heat dissipating segment, two opposite end portions of the loading segment are respectively defined as a mounting end portion and a connecting end portion, and two opposite end portions of the heat dissipating segment are respectively defined as a positioning end portion and a free end portion. The connecting end portion is connected to the positioning end portion. A thickness of the loading segment is greater than that of the heat dissipating segment. When the magnetic actuation is driven by a magnetic field to swing the blade, a swing angle of the free end portion of the heat dissipating segment is greater than that of the connecting end portion of the loading segment.

### BACKGROUND OF THE INVENTION

1. Field of the Invention

The instant invention relates to a heat dissipating device; in particular, to a heat dissipating device and a swing structure thereof.

2. Description of Related Art

With the rapid development of electronic products, whether laptop, desktop, or tablet, etc., the effectiveness of the central processor and other electronic components has had great improvement. However, if the volume of the electronic component remains unchanged or is decreased, the heat generated from an operating electronic component (e.g., heat generating member) will increase. If heat cannot dissipate effectively, heat will cause the electronic component to have high temperature, which influences the operation of the electronic component. For example, heat usually causes thermal shutdown of a heat generating member. The conventional solution is disposing a heat dissipating fan on a heat generating member, thereby reducing the temperature of the heat generating member.

Moreover, the size of the conventional heat dissipating fan remains unchanged, so the conventional heat dissipating fan cannot entirely align with each kind of heat generating member, thus part of the heat generating member is not arranged in a heat dissipating area defined by the conventional heat dissipating fan. In other words, the heat dissipating fan is not easily customized. Accordingly, the inventor has provided a heat dissipating device, which is easily customized. How to improve the heat dissipating effect of the heat dissipating device is one of the inventor's major concerns.

### SUMMARY OF THE INVENTION

The instant disclosure provides a heat dissipating system and a swing structure thereof for effectively improving the heat dissipating effect.

The instant disclosure provides a heat dissipating device, comprising: a carrier module; a magnetic driving module disposed on the carrier module, wherein the magnetic driving module is configured to generate a magnetic field, the magnetic field defines two magnetic areas respectively having two opposite magnetisms, and the magnetic driving module is configured to cyclically change the magnetisms of the two magnetic areas by receiving a periodic power; and a swing module disposed on the carrier module and having at least two swing structures, each swing structure comprising: an elongated blade having a loading segment and a heat dissipating segment, wherein two opposite end portions of the loading segment are respectively defined as a mounting end portion and a connecting end portion, two opposite end portions of the heat dissipating segment are respectively defined as a positioning end portion and a free end portion, wherein the connecting end portion of the loading segment is connected to the positioning end portion of the heat dissipating segment; and a magnetic actuation disposed on a portion of the loading segment between the mounting end portion and the connecting end portion; wherein the two blades are parallel to each other, the two mounting end portions of the two loading segments are respectively fastened on two opposite sides of the carrier module, and the two magnetic actuations are respectively arranged in the two magnetic areas; when the magnetic driving module generates the magnetic field, the two magnetic actuations are moved by the two magnetic areas to swing the two blades, and a swing angle of the free end portion of each heat dissipating segment is greater than a swing angle of the connecting end portion of the connected loading segment.

The instant disclosure also provides a swing structure of a heat dissipating device, comprising: an elongated blade having a loading segment and a heat dissipating segment, wherein two opposite end portions of the loading segment are respectively defined as a mounting end portion and a connecting end portion, two opposite end portions of the heat dissipating segment are respectively defined as a positioning end portion and a free end portion, wherein the connecting end portion of the loading segment is connected to the positioning end portion of the heat dissipating segment, a thickness of the loading segment is greater than that of the heat dissipating segment; and a magnetic actuation disposed on a portion of the loading segment between the mounting end portion and the connecting end portion; wherein when the magnetic actuation is driven by a magnetic field to swing the blade, a swing angle of the free end portion of the heat dissipating segment is greater than a swing angle of the connecting end portion of the loading segment.

In summary, the heat dissipating device in the instant disclosure is provided with the particular swing structure, so when each blade is swung, the swing angle of the free end portion of each heat dissipating segment is greater than that of the connecting end portion of the connected loading segment, thereby increasing the heat dissipating effect of the heat dissipating device.

In order to further appreciate the characteristics and technical contents of the instant invention, references are hereunder made to the detailed descriptions and appended drawings in connection with the instant invention. However, the appended drawings are merely shown for exemplary purposes, rather than being used to restrict the scope of the instant invention.

### BRIEF DESCRIPTION OF THE DRAWINGS

FIG. 1 is a perspective view showing a heat dissipating device according to a first embodiment of the instant disclosure;

FIG. 2 is an exploded view of FIG. 1;

FIG. 3 is a front view of FIG. 1;

FIG. 4 is an operating view of FIG. 3;

FIG. 5 is a perspective view showing a swing structure of the heat dissipating device according to a second embodiment of the instant disclosure;

FIG. 6 is a cross-sectional view of FIG. 5;

FIG. 7 is a perspective view showing a swing structure of the heat dissipating device according to a third embodiment of the instant disclosure;

FIG. 8 is a perspective view showing a swing structure of the heat dissipating device according to a fourth embodiment of the instant disclosure; and

FIG. 9 is a functional block view of the heat dissipating device according to a fifth embodiment of the instant disclosure.

### DETAILED DESCRIPTION OF THE PREFERRED EMBODIMENTS

### First Embodiment

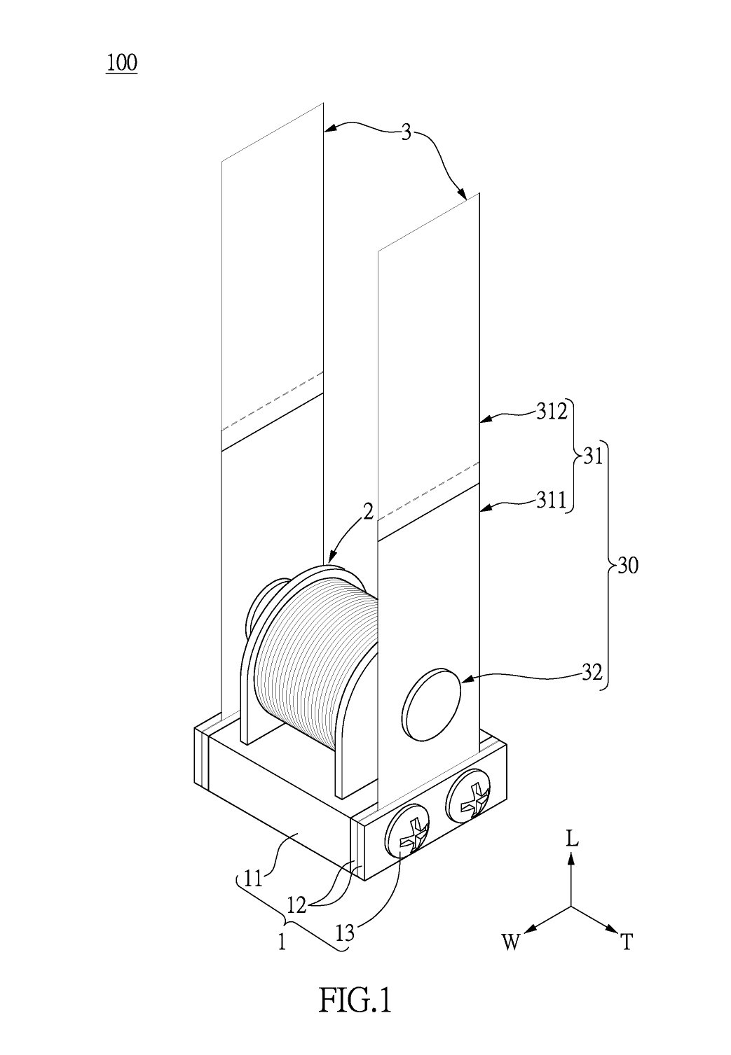

Please refer to FIGS. 1 through 4, which show a first embodiment of the instant disclosure. References are hereunder made to the detailed descriptions and appended drawings in connection with the instant invention. However, the appended drawings are merely shown for exemplary purposes, rather than being used to restrict the scope of the instant invention.

The instant disclosure provides a heat dissipating device 100; in particular, to a heat dissipating device 100 provided to dissipate heat by at least one swing structure 30. The heat dissipating device 100 includes a carrier module 1, a magnetic driving module 2, and a swing module 3. The magnetic driving module 2 and the swing module 3 are fastened on the carrier module 1, and the swing module 3 is corresponding in position to the magnetic driving module 2. The following description discloses the possible construction of the heat dissipating device 100, but is not limited thereto.

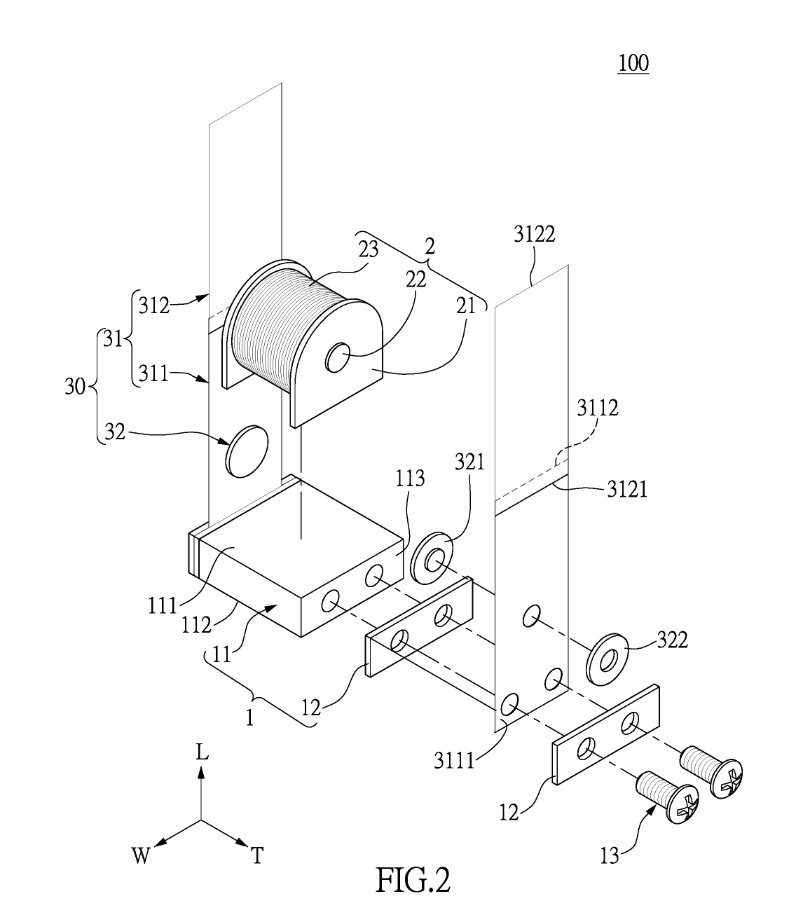

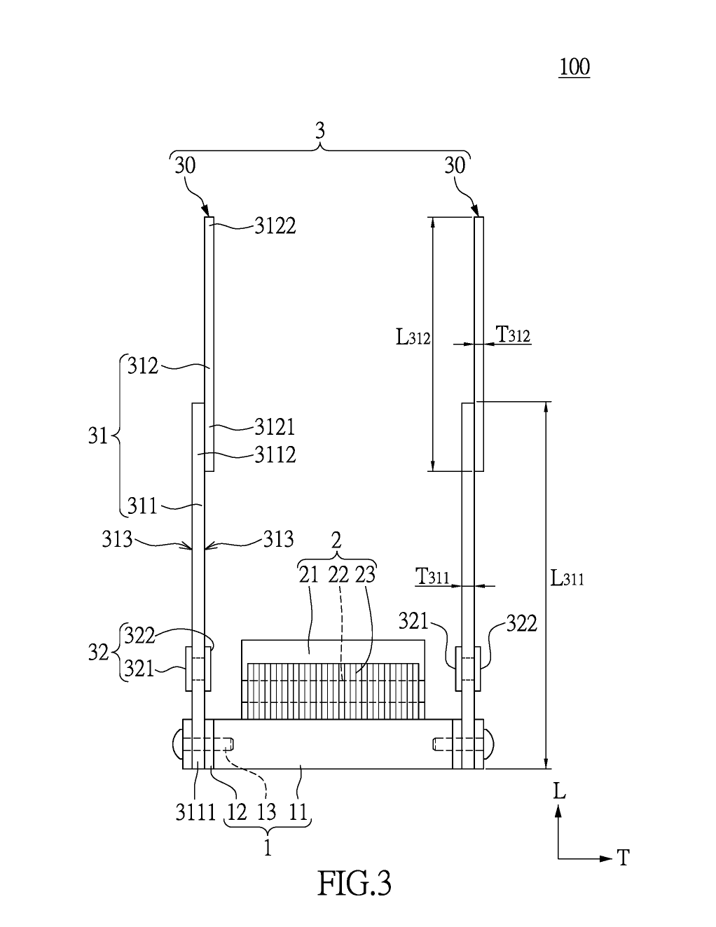

As shown in FIGS. 2 and 3, the carrier module 1 includes a base seat 11, a plurality of buffering pads 12 respectively disposed on two opposite sides of the base seat 11, and a plurality of screws 13. The base seat 11 has a first surface 111 (i.e., the top surface of the base seat 11 shown in FIG. 2), a second surface 112 (i.e., the bottom surface of the base seat 11 shown in FIG. 2), and two opposite side surfaces 113 (i.e., the left side surface and the right side surface of the base seat 11 shown in FIG. 2) arranged between the first surface 111 and the second surface 112. Moreover, the buffering pads 13 are screwed on the two side surfaces 113 of the base seat 11 by using the screws 13, and at least two of the buffering pads 13 are stacked on each side surface 113 of the base seat 11.

The magnetic driving module 2 is disposed on the first surface 111 of the base seat 11 of the carrier module 1 for generating a magnetic field (not shown), and the magnetic field defines two magnetic areas (not shown, such as the left side space and the right side space of the magnetic driving module 2 shown in FIG. 3) respectively having two opposite magnetisms. The magnetic driving module 2 is configured to cyclically change the magnetisms of the two magnetic areas by receiving a periodic power (not shown). The periodic power can be periodic square wave, periodic triangle wave, periodic sine wave, or the positive and negative half-cycle period of alternating current. The periodic power in the instant embodiment is the positive and negative half-cycle period of alternating current as an example.

Specifically, the magnetic driving module 2 in the instant embodiment has a frame 21, an elongated core 22 (i.e., iron core) installed on the frame 21, and a coil 23 winding around the core 22 and installed on the frame 21. A longitudinal direction of the core 22 is approximately parallel to a distance between the two side surfaces 113 of the base seat 11. The coil 23 is electrically connected to the periodic power, so when the periodic power emits a current to travel in the coil 23, the coil 23 and the core 22 generate a magnetic field, thus the magnetisms of the two magnetic areas are cyclically changed as time goes on.

The swing module 3 includes at least two swing structures 30 respectively disposed adjacent to the two side surfaces 113 of the base seat 11 of the carrier module 1. Because the two swing structures 30 are almost the same, the following description only discloses the construction of one of the two swing structures 30, and then discloses the relationship between the two swing structures 30.

The swing structure 30 has an elongated blade 31 and a magnetic actuation 32 disposed on the blade 31. The blade 31 has a loading segment 311 and a heat dissipating segment 312 connected to the loading segment 311, and a thickness T₃₁₁ of the loading segment 311 is greater than a thickness T₃₁₂ of the heat dissipating segment 312. Two opposite end portions of the loading segment 311 (i.e., the bottom portion and the top portion of the loading segment 311 shown in FIG. 3) are respectively defined as a mounting end portion 3111 and a connecting end portion 3112. Two opposite end portions of the heat dissipating segment 312 (i.e., the bottom portion and the top portion of the heat dissipating segment 312 shown in FIG. 3) are respectively defined as a positioning end portion 3121 and a free end portion 3122. The connecting end portion 3112 of the loading segment 311 is connected to the positioning end portion 3121 of the heat dissipating segment 312. The connection between the connecting end portion 3112 and the positioning end portion 3121 can be implemented by adhering, screwing, or other manner.

It should be noted that a longitudinal direction of the blade 31 defines a longitudinal direction L, the blade 31 has two parallel board surfaces 313 defining a thickness direction T parallel to a distance between the board surfaces 313, and the longitudinal direction L and the thickness direction T are perpendicular to each other for further defining a width direction W, which is perpendicular to the longitudinal direction L and the thickness direction T.

The magnetic actuation 32 is disposed on a portion of the loading segment 311 between the mounting end portion 3111 and the connecting end portion 3112. The magnetic actuation 32 in the instant embodiment includes two magnets 321, 322, which are magnetically attracted and engaged to each other. The magnet 321 is partially inserted into a thru-hole of the loading segment 311 in the thickness direction T to engage with the other magnet 322. In addition, the two magnets 321, 322 can be adhered on the two opposite board surfaces 313 of the loading segment 311 (not shown), and the installing method of the magnets 321, 322 is not limited to the instant embodiment.

Specifically, each swing structure 30 in the instant embodiment only has the single magnetic actuation 32. In other words, the heat dissipating segment 312 or the connecting portion between the loading segment 311 and the heat dissipating segment 312 of each swing structure 30 is provided without disposing any magnetic actuation 32. If a non-shown swing structure is provided with a magnetic actuation 32 disposed on the heat dissipating segment 312 or the connecting portion between the loading segment 311 and the heat dissipating segment 312, the heat dissipating effect and the service life of the blade 32 of this non-shown swing structure will be reduced due to the position of the magnetic actuation 32, and this non-shown swing structure is not the swing structure 30 provided by the instant embodiment. Moreover, the shape of the blade 31 can be changed according to a designer's demand, and is not limited to the rectangular shape of the instant embodiment.

The construction of the single swing structure 30 has been disclosed in the above description, and the following description discloses the relationship between the two swing structures 30. The mounting end portions 3111 of the two loading segments 311 of the two blades 31 are respectively fastened on the two opposite sides of the base seat 11 of the carrier module 1 by using the screws 13. The mounting end portion 3111 of each loading segment 311 is clamped by the at least two buffering pads 12 arranged on one side of the base seat 11, and the two blades 31 are approximately parallel to each other. The two magnetic actuations 32 are respectively arranged in the two magnetic areas, and the adjacent portions of the magnetic actuations 32 (i.e., the magnet 322 of the left swing structure 30 and the magnet 321 of the right swing structure 30 shown in FIG. 3) are respectively provided with two opposite magnetisms.

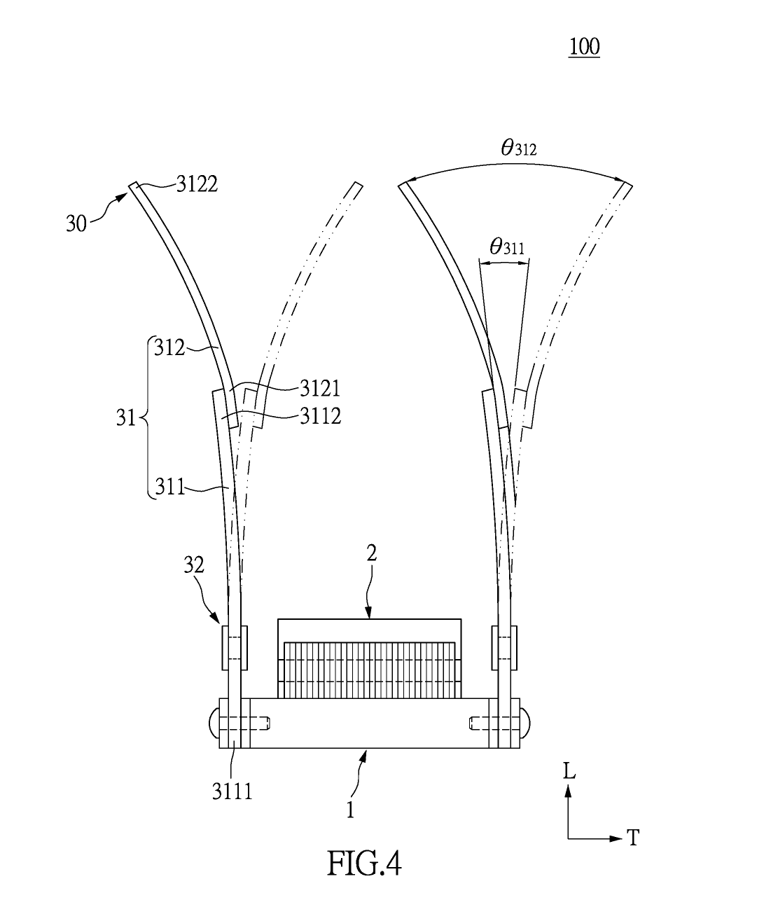

Thus, when the magnetic driving module 2 generates the magnetic field (as shown in FIG. 4), the two magnetic actuations 32 are slightly moved by the two magnetic areas to swing the two blades 31, and a swing angle θ₃₁₂ of the free end portion 3122 of each heat dissipating segment 312 is greater than a swing angle θ₃₁₁ of the connecting end portion 3112 of the connected loading segment 311, thereby increasing the heat dissipating effect of the heat dissipating device 100. Specifically, when a portion of the magnetic actuation 32 arranged adjacent to the magnetic driving module 2 has a magnetism, which is opposing to the magnetism of the corresponding magnetic area, the magnetic actuation 32 is moved toward the magnetic driving module 2; when a portion of the magnetic actuation 32 arranged adjacent to the magnetic driving module 2 has a magnetism, which is identical to the magnetism of the corresponding magnetic area, the magnetic actuation 32 is moved away from the magnetic driving module 2.

Furthermore, each swing structure 30 of the heat dissipating device 100 can be provided with the following limitations for further increasing the heat dissipating effect of the heat dissipating device 100. A Young's modulus of each loading segment 311 is greater than a Young's modulus of the connected heat dissipating segment 312. A ratio (i.e., L₃₁₂/L₃₁₁) between a length L₃₁₂ of each heat dissipating segment 312 corresponding to the longitudinal direction L and a length L₃₁₁ of the connected loading segment 311 corresponding to the longitudinal direction L is approximately 0.3˜5. A ratio (i.e., T₃₁₂/T₃₁₁) between a thickness T₃₁₂ of each heat dissipating segment 312 corresponding to the thickness direction T and a thickness T₃₁₁ of the connected loading segment 311 corresponding to the thickness direction T is approximately 0.1˜1.

As shown in FIG. 4, when the magnetic driving module 2 generates the magnetic field to swing the two blades 31, the swing angle θ₃₁₁ of the connecting end portion 3112 of each loading segment 311 is preferably less than 15 degrees, and the swing angle θ₃₁₂ of the free end portion 3122 of each heat dissipating segment 312 is preferably greater than 15 degrees and less than 45 degrees.

The heat dissipating device 100 of the first embodiment has been disclosed in the above description, and any portion of the heat dissipating device 100 can be provided with different construction. For clearly explaining the instant disclosure, the following embodiments disclose the possible different constructions. In other words, each of the following embodiments can be used to replace or add onto the corresponding portion of the first embodiment to construct a heat dissipating device 100 different from the first embodiment.

### Second Embodiment

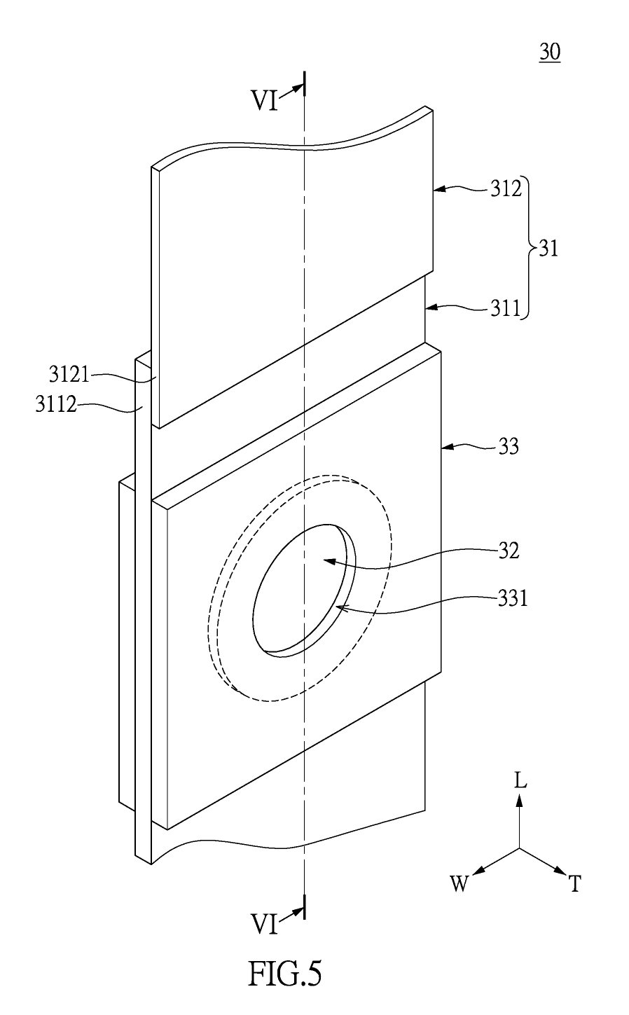

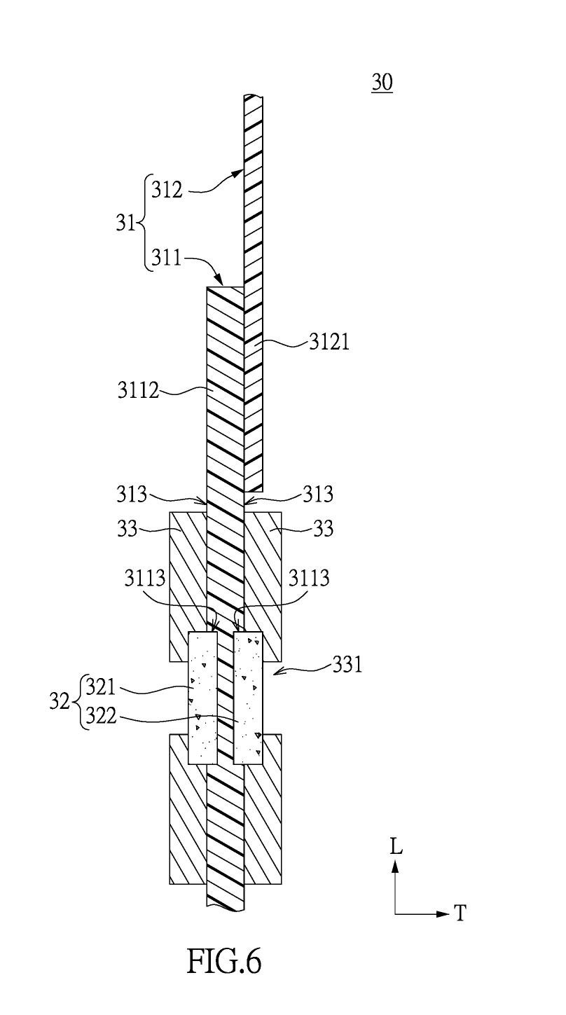

Please refer to FIGS. 5 and 6, which show a second embodiment of the instant disclosure. The instant embodiment is similar to the first embodiment, and the same features are not disclosed again. The main difference between the two embodiments is the swing structure 30.

Specifically, for each swing structure 30 in the instant embodiment, the loading segment 311 has two engaging troughs 3113 respectively recessed on the two board surfaces 313 thereof, the two magnets 321, 322 of the magnetic actuation 32, which are magnetically attracted with each other, are respectively fixed in the two engaging troughs 3113 of the loading segment 311, and part of each magnets 321, 322 is protruded from the corresponding engaging trough 3113. In addition, in a non-shown embodiment, the loading segment 311 can be provided with an engaging trough 3113 recessed on one of the two board surfaces 313 thereof, and one of the two magnets 321, 322 of the magnetic actuation 32 is fixed in the engaging trough 3113 of the loading segment 311.

Moreover, each swing structure 30 further includes two positioning covers 33. The two positioning covers 33 are respectively disposed on the two board surfaces 313 of the loading segment 311. The two positioning covers 33 are respectively abutted against two portions of the two magnets 321, 322, which are protruded from the corresponding engaging troughs 3113. A center portion of each positioning cover 33 has a thru-hole 331 for exposing a portion of the abutted magnet 321, 322.

### Third Embodiment

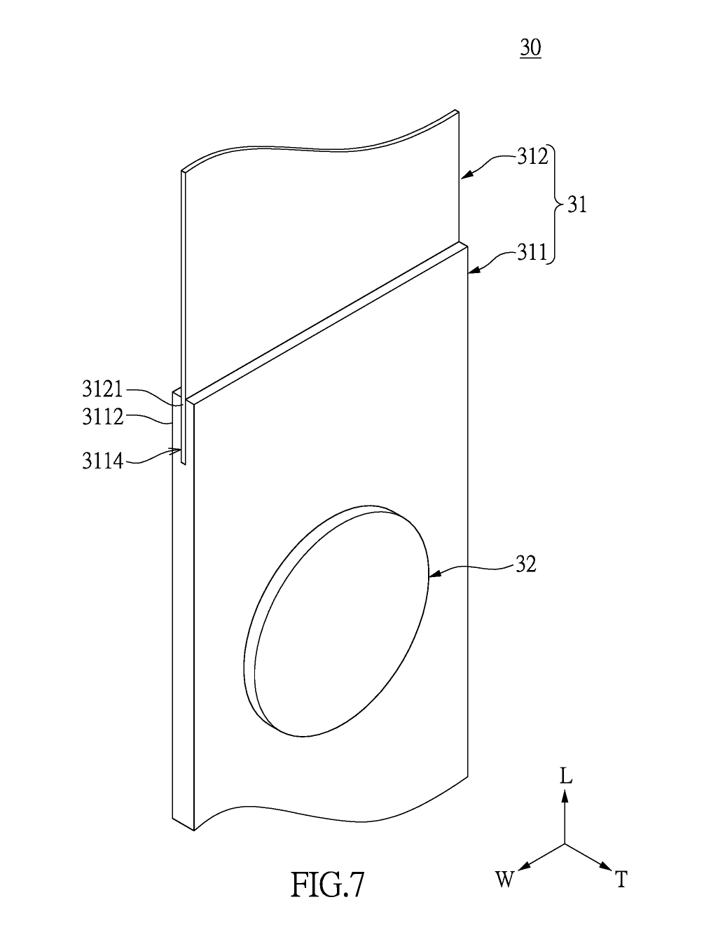

Please refer to FIG. 7, which shows a third embodiment of the instant disclosure. The instant embodiment is similar to the first embodiment, and the same features are not disclosed again. The main difference between the two embodiments is the swing structure 30.

Specifically, for each swing structure 30 in the instant embodiment, an edge of the connecting end portion 3112 of the loading segment 311 (i.e., the top edge of the loading segment 311 shown in FIG. 7) has a connecting groove 3114, and the positioning end portion 3121 of the heat dissipating segment 312 is inserted into and is fastened in the connecting groove 3114. The connection between the positioning end portion 3121 of the heat dissipating segment 312 and the connecting groove 3114 of the loading segment 311 can be implemented by screwing, adhering, or the other manner. For example, the loading segment 311 and the heat dissipating segment 312 of each blade 31 in the instant disclosure can be formed in an integral construction by using a double-shot molding.

### Fourth Embodiment

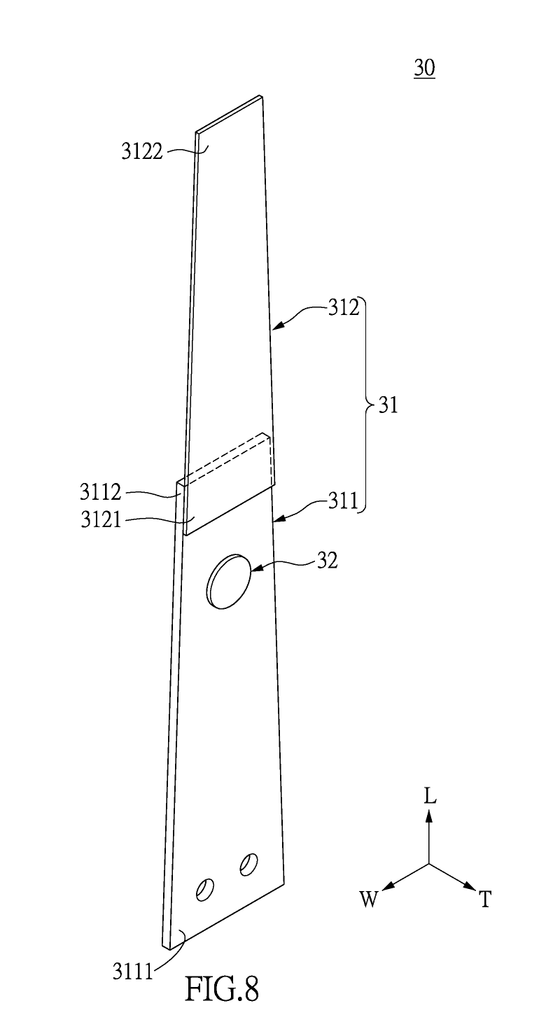

Please refer to FIG. 8, which shows a fourth embodiment of the instant disclosure. The instant embodiment is similar to the first embodiment, and the same features are not disclosed again. The main difference between the two embodiments is the swing structure 30.

Specifically, for each swing structure 30 in the instant embodiment, the width of each blade 31 corresponding to the width direction W gradually reduces from the mounting end portion 3111 of the loading segment 311 to the free end portion 3122 of the heat dissipating segment 312. Specifically, each blade 31 of the instant embodiment has a trapezoid shape, but is not limited thereto.

### Fifth Embodiment

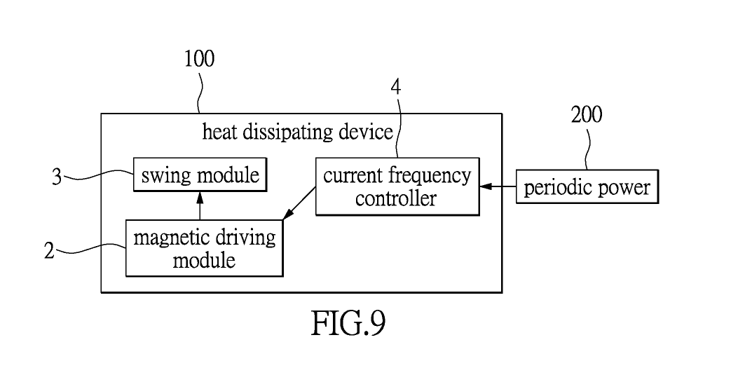

Please refer to FIG. 9, which shows a fifth embodiment of the instant disclosure. The instant embodiment is similar to the above embodiments, and the same features are not disclosed again. The main difference in the instant embodiment is the heat dissipating device 100 is provided with a current frequency controller 4.

Specifically, the current frequency controller 4 is electrically connected to the magnetic driving module 2 for adjusting a frequency of the periodic power 200. Accordingly, a resonance frequency of each heat dissipating segment 312 is preferably different from a resonance frequency of the connected loading segment 311. The current frequency controller 4 is configured to adjust the frequency of the periodic power 200 to be identical to the resonance frequency of each heat dissipating segment 312, thereby increasing the swing angle of each heat dissipating segment 312.

### [The Possible Effect of the Instant Disclosure]

In summary, the heat dissipating device in the instant disclosure is provided with the particular swing structure, so when each blade is swung, the swing angle of the free end portion of each heat dissipating segment is greater than that of the connecting end portion of the connected loading segment, thereby increasing the heat dissipating effect of the heat dissipating device.

Moreover, the heat dissipating device in the instant disclosure can be provided with the current frequency controller electrically connected to the magnetic driving module for adjusting a frequency of the periodic power to be identical to the resonance frequency of each heat dissipating segment, thereby increasing the swing angle of each heat dissipating segment.

The descriptions illustrated supra set forth simply the preferred embodiments of the instant invention; however, the characteristics of the instant invention are by no means restricted thereto. All changes, alterations, or modifications conveniently considered by those skilled in the art are deemed to be encompassed within the scope of the instant invention delineated by the following claims.

What is claimed is:

1. A heat dissipating device, comprising:
a carrier module;
a magnetic driving module disposed on the carrier module, wherein the magnetic driving module is configured to generate a magnetic field, the magnetic field defines two magnetic areas respectively having two opposite magnetisms, and the magnetic driving module is configured to cyclically change the magnetisms of the two magnetic areas by receiving a periodic power; and
a swing module disposed on the carrier module and having at least two swing structures, each swing structure comprising:
an elongated blade having a loading segment and a heat dissipating segment, wherein two opposite end portions of the loading segment are respectively defined as a mounting end portion and a connecting end portion, two opposite end portions of the heat dissipating segment are respectively defined as a positioning end portion and a free end portion, wherein the connecting end portion of the loading segment is connected to the positioning end portion of the heat dissipating segment; and
a magnetic actuation disposed on a portion of the loading segment between the mounting end portion and the connecting end portion;
wherein the two blades are parallel to each other, the two mounting end portions of the two loading segments are respectively fastened on two opposite sides of the carrier module, and the two magnetic actuations are respectively arranged in the two magnetic areas; when the magnetic driving module generates the magnetic field, the two magnetic actuations are moved by the two magnetic areas to swing the two blades, and a swing angle of the free end portion of each heat dissipating segment is greater than a swing angle of the connecting end portion of the connected loading segment.

2. The heat dissipating device as claimed in claim 1, wherein when the magnetic driving module generates the magnetic field to swing the two blades, the swing angle of each loading segment is less than 15 degrees, and the swing angle of each heat dissipating segment is greater than 15 degrees and less than 45 degrees.

3. The heat dissipating device as claimed in claim 1, wherein each blade defines a longitudinal direction; a ratio between a length of the heat dissipating segment corresponding to the longitudinal direction and a length of the loading segment corresponding to the longitudinal direction in each blade is approximately 0.3˜5.

4. The heat dissipating device as claimed in claim 1, wherein each blade has two parallel board surfaces, and a distance between the two board surfaces defines a thickness direction; a ratio between a thickness of the heat dissipating segment corresponding to the thickness direction and a thickness of the loading segment corresponding to the thickness direction in each blade is approximately 0.1˜1.

5. The heat dissipating device as claimed in claim 1, wherein each blade has two parallel board surfaces, and a distance between the two board surfaces defines a thickness direction; for each swing structure, the loading segment has an engaging trough recessed on one of the two board surfaces thereof, the magnetic actuation has at least one magnet fixed in the engaging trough of the loading segment.

6. The heat dissipating device as claimed in claim 1, wherein the loading segment and the heat dissipating segment of each blade are formed in an integral construction by using a double-shot molding.

7. The heat dissipating device as claimed in claim 1, wherein for each blade, an edge of the connecting end portion of the loading segment arranged away from the mounting end portion has a connecting groove, the positioning end portion of the heat dissipating segment is inserted into and is fastened in the connecting groove.

8. The heat dissipating device as claimed in claim 1, further comprising a current frequency controller electrically connected to the magnetic driving module for adjusting a frequency of the periodic power, wherein a resonance frequency of each heat dissipating segment is different from a resonance frequency of the connected loading segment, and the current frequency controller is configured to adjust the frequency of the periodic power to be identical to the resonance frequency of each heat dissipating segment.

9. A swing structure of a heat dissipating device, comprising:
an elongated blade having a loading segment and a heat dissipating segment, wherein two opposite end portions of the loading segment are respectively defined as a mounting end portion and a connecting end portion, two opposite end portions of the heat dissipating segment are respectively defined as a positioning end portion and a free end portion, wherein the connecting end portion of the loading segment is connected to the positioning end portion of the heat dissipating segment, a thickness of the loading segment is greater than that of the heat dissipating segment; and
a magnetic actuation disposed on a portion of the loading segment between the mounting end portion and the connecting end portion; wherein when the magnetic actuation is driven by a magnetic field to swing the blade, a swing angle of the free end portion of the heat dissipating segment is greater than a swing angle of the connecting end portion of the loading segment.

10. The swing structure as claimed in claim 9, wherein the blade defines a longitudinal direction; a ratio between a length of the heat dissipating segment corresponding to the longitudinal direction and a length of the loading segment corresponding to the longitudinal direction is approximately 0.3˜5; the blade has two parallel board surfaces, and a distance between the two board surfaces defines a thickness direction; a ratio between a thickness of the heat dissipating segment corresponding to the thickness direction and a thickness of the loading segment corresponding to the thickness direction is approximately 0.1˜1.
